(19) United States
(12) Patent Application Publication
(10) Pub. No.: US 2025/0133965 A1
(43) Pub. Date: Apr. 24, 2025

(54) SELECTIVE ETCHING OF SCANDIUM-DOPED ALUMINUM NITRIDE

(71) Applicant: Applied Materials, Inc., Santa Clara, CA (US)

(72) Inventors: Vijay Bhan Sharma, Bharatpur (IN); Bharatwaj Ramakrishnan, San Jose, CA (US); Sukti Chatterjee, San Jose, CA (US)

(73) Assignee: Applied Materials, Inc., Santa Clara, CA (US)

(21) Appl. No.: 18/688,260

(22) PCT Filed: Aug. 25, 2022
(86) PCT No.: PCT/US2022/041593

§ 371 Date: Feb. 29, 2024

(30) Foreign Application Priority Data
Sep. 2, 2021 (IN) 202141039722

(51) Int. Cl. H10N 30/082; C09K 13/04; H10N 30/853

(52) U.S. Cl. CPC H10N 30/082; C09K 13/04; H10N 30/853

(57) ABSTRACT

Exemplary substrate processing methods are described. The methods may include providing a scandium-doped aluminum nitride layer on a metal layer. They may further include etching a portion of the scandium-doped aluminum nitride layer with an etching composition. The etching composition may include greater than or about 80 wt. % phosphoric acid. The compositions may further be characterized by a temperature of greater than or about 90° C. during etching.

### CROSS REFERENCE TO RELATED APPLICATIONS

This application claims the benefit of India patent application No. 202141039722 filed Sep. 2, 2021, which the entire disclosure of which is incorporated by reference herein for all purposes.

### TECHNICAL FIELD

The present technology relates to etching operations in substrate processing. More specifically, the present technology relates to methods and structures to perform chemical etchings of scandium-doped aluminum nitride in piezoelectric structures.

### BACKGROUND

Metal-insulator-metal (MIM) devices are made possible by processes which produce intricately patterned material layers on substrate surfaces. These processes include the formation of metal and insulating layers that can be fabricated into micron-sized devices on the substrate which are capable of physical actuation and the processing of electrical signals. In many instances, the structure of these devices is formed by patterned etching operations that pattern one or more layers of metal, insulating, and piezoelectric materials deposited on the substrate into the device structure.

In many cases, the etching operations use wet etchants that are able to form openings, steps, and other structures on a micron-sized scale into the layers. Wet etchants are normally able to etch significantly more material than gas or plasma etchants, which makes them better suited in many cases for rapidly producing many kinds of MIM devices. However, wet etchants can be more difficult to control in an etching operation than dry and plasma etchants, and can often overetch the layers they are patterning. In order to control the probability and extent of overetching, etching operations are often adjusted to slow the etch rate. Unfortunately, slower etch rates result in longer etch times and a reduced throughput of patterned substrates for the MIM devices.

Thus, there is a need for improved systems and methods that can be used to produce high-quality MIM devices and structures. These and other needs are addressed by the present technology.

### SUMMARY

Embodiments of the present technology include substrate processing methods that include providing a scandium-doped aluminum nitride layer on a metal layer. The methods further include etching a portion of the scandium-doped aluminum nitride layer with an etching composition. The etching composition is characterized by a temperature of greater than or about 90° C. during etching.

In additional embodiments, the etching composition is free of nitric acid. In further embodiments, the etching composition is free of potassium hydroxide and tetramethyl ammonium hydroxide. In still further embodiments, the etching composition etches the scandium-doped aluminum nitride layer at an etch rate of greater than or about 110 nm/min. In yet additional embodiments, the etching composition etches the metal layer at an etch rate of less than or about 1 nm/hour. In more embodiments, a patterned photoresist having one or more openings is formed on the scandium-doped aluminum nitride layer, and the etching composition etches a portion of scandium-doped aluminum nitride layer through the one or more openings in the patterned photoresist. In still more embodiments, the scandium-doped aluminum nitride layer includes greater than or about 30 mol. % scandium. In yet further embodiments, the metal layer include molybdenum.

Embodiments of the present technology also include substrate processing methods that include providing a substrate. The substrate includes a scandium-doped aluminum nitride layer on a metal layer. The methods also include forming a patterned photoresist layer on the scandium-doped aluminum nitride layer, where the patterned photoresist layer includes one or more openings that expose a portion of the scandium-doped aluminum nitride layer. The methods further include contacting the substrate with an etching solution. The etching solution is characterized by a temperature greater than or about 90° C. and a phosphoric acid concentration of greater than or about 80 wt. %. The methods still further include etching the exposed portion of the scandium-doped aluminum nitride layer with the etching solution.

In additional embodiments, the etching solution is free of nitric acid, potassium hydroxide, and tetramethyl ammonium hydroxide. In further embodiments, the etching solution is characterized by an etch rate selectivity ratio for the scandium-doped aluminum layer over the metal layer of greater than or about 10,000:1. In still further embodiments, the etching solution etches the scandium-doped aluminum nitride layer at a first etch rate of greater than or about 110 nm/min, and etches the metal layer at a second etch rate of less than or about 1 nm/hour. In more embodiments, the scandium-doped aluminum nitride layer includes greater than or about 30 mol. % scandium. In yet more embodiments, the metal layer includes molybdenum.

Embodiments of the present technology further include structured substrates that include a silicon-containing material and a first metal layer in contact with the silicon-containing material. The structured substrates may also include a patterned scandium-doped aluminum nitride layer in contact with the first metal layer, wherein the scandium-doped aluminum nitride layer includes greater than or about 30 mol. % scandium. The structured substrates may further include a second metal layer in contact with a surface of the patterned scandium-doped aluminum nitride layer opposite a surface in contact with the first metal layer.

In additional embodiments, the silicon-containing material includes a silicon oxide layer in contact with the first metal layer and a silicon layer in contact with the silicon oxide layer. In further embodiments, the structured substrates further include an undoped aluminum nitride layer in contact with the silicon-containing material and the first metal layer. In still further embodiments, the first metal layer may include unalloyed molybdenum.

In more embodiments, the second metal layer may include molybdenum. In still more embodiments, the first metal layer lacks an overetched recess above a gap in the patterned scandium-doped aluminum nitride layer.

Embodiments of the present technology provide numerous benefits over conventional technology to form MIM devices that include piezoelectric materials such as bulk-acoustic-wave devices. For example, the embodiments of the present technology permit the highly-selective etching of scandium-doped aluminum nitride (ScAlN) layers form on metal layers that can function as electrodes for piezoelectric ScAlN layers. The highly-selective etching permits a complete etch of the ScAlN material down to the surface of the metal layer with little or no overetching of the metal. The high selectivity of the etching compositions permit them to etch at increased temperatures that increase the etch rate, reduce the time for the etching operation, and increase the throughput of the patterned substrates.

These and other embodiments, along with many of their advantages and features, are described in more detail in conjunction with the below description and attached figures.

### BRIEF DESCRIPTION OF THE DRAWINGS

A further understanding of the nature and advantages of the disclosed embodiments may be realized by reference to the remaining portions of the specification and the drawings.

FIG. 1 shows exemplary operations in a method of selectively etching a scandium-doped aluminum nitride material according to embodiments of the present technology.

FIG. 2A shows a partial cross-sectional view of a substrate structure according to embodiments of the present technology.

FIG. 2B shows another partial cross-sectional view of a substrate structure according to embodiments of the present technology.

FIG. 2C shows another partial cross-sectional view of a substrate structure according to embodiments of the present technology.

FIG. 2D shows another partial cross-sectional view of a substrate structure according to embodiments of the present technology.

FIG. 2E shows another partial cross-sectional view of a substrate structure according to embodiments of the present technology.

FIG. 2F shows another partial cross-sectional view of a substrate structure according to embodiments of the present technology.

FIG. 3A shows a planar view of a portion of a MIM device according to embodiments of the present technology.

FIG. 3B shows a cross-sectional view of regions of the MIM device according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the figures, similar components and/or features may have the same numerical reference label. Further, various components of the same type may be distinguished by following the reference label by a letter that distinguishes among the similar components and/or features. If only the first numerical reference label is used in the specification, the description is applicable to any one of the similar components and/or features having the same first numerical reference label irrespective of the letter suffix.

### DETAILED DESCRIPTION

Piezoelectric metal-insulator-metal (MIM) devices include an electrically-insulating layer of piezoelectric material positioned between a pair of electrically-conducting metal layers that form the device's electrodes. Mechanical oscillations, such as acoustic waves, created in the piezoelectric material can cause changes in the electric field of the material that can be propagated by the electrodes. Conversely, changes applied to an electric field in the piezoelectric material by the electrodes can create mechanical oscillations in the piezoelectric material. The coupling between electrical and mechanical excitation in piezoelectric materials has a number of practical uses in electronic devices. One such use is acoustic wave resonance that permits the MIM device to act as multiplexable transmission and reception module in a mobile communication device. Modules made of these MIM materials can be reduced to micron scales or less to create very compact radio and microwave signal transmitters and receivers in mobile phones and other kinds of mobile devices.

A piezoelectric material that is useful in MIM devices for high-bandwidth mobile communications, among other electronics applications, is aluminum nitride (AlN). Unfortunately, MIM device fabricators are reaching some performance limits with the thermal stability and piezoelectric efficiency of undoped AlN. They are turning to doped AlN materials to increase these limits, and are focusing their attention in particular on scandium-doped aluminum nitride materials (ScAlN). Scandium doping can increase the piezoelectric thermal stability of aluminum nitride and enhance additional piezoelectric characteristics, such as the piezoelectric coefficient, that make the piezoelectric material more power-efficient.

Increased levels of scandium doping create fabrication challenges for the efficient production MIM structures. Introducing scandium to the aluminum nitride renders alkaline wet etchants such as potassium hydroxide (KOH) and tetramethyl ammonium hydroxide (TMAH) less effective, especially when the underlying metal electrode layer includes molybdenum. The alkaline wet etchants have low etch rate selectivity for the highly-doped ScAlN relative to the underling metal, and in many cases the etch operation cannot be stopped before the metal layer has been etched away with the ScAlN material. Acidic wet etchants, such as phosphoric acid (H₃PO₄), are less efficient as the scandium doping level increases. Attempts to increase the efficiency of the acidic wet etchants include combining the phosphoric acid with nitric acid (HNO₃). However, introducing nitric acid into the phosphoric acid etching solution significantly reduces the selectivity for etching the ScAlN layer over the adjacent metal layers, and creates a low-selectivity problem similar to the one seen with alkaline wet etchants. The concern about the etching composition overetching the ScAlN layer into the underlying metal layer has caused the etching operation to be run at lower etch rates to better control the endpoint of the etch. The temperature of the phosphoric acid-containing etching solution is kept at 85° C. or less in order to slow the etch rate of the ScAlN layer to 100 nm/min or less. Unfortunately, the reduced etch rate results in a longer etch time for the etching operation. An etching operation through a 1 micron think ScAlN layer takes greater than or about 10 minutes, resulting in a low throughput of substrates for the etching operation.

Embodiments of the present technology address problems with the low etching efficiency of wet etching compositions with low selectivity for etching scandium-doped aluminum nitride over adjacent metal lines. In the present invention, it has been discovered that phosphoric acid etching solutions that lack additional strong inorganic acids such as nitric acid are highly selective for etching scandium-doped aluminum nitride over metal. The high etch selectivity is further increased with increased levels of scandium doping and the incorporation of molybdenum in the metal layers. The high selectivity permits the etching operation to be performed in high etching rates of greater than or about 110 nm/min without concerns that the etching solution will overetch the ScAlN layer into the underlying metal layer. The faster etching rates are achieved by increasing the temperature of the etching solution to greater than or about 90° C.

Embodiments of the present technology significantly reduce the time for the ScAlN etching operation without any significant removal of an underlying metal layer. In embodiments, the etching operation can be completed in less than or about 5 minutes for the etch of a 1 micron thick ScAlN layer. The shortened etch times can be realized even as the scandium doping levels in the aluminum nitride are increased to greater than or about 30 mol. %. In embodiments, the highly selective etching operations can reduce the etch time to less than or about 50% of the time required for conventional wet etching operations with lower temperature etching solutions.

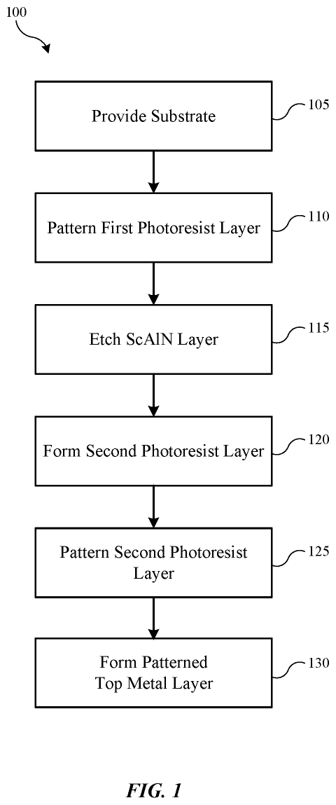

FIG. 1 shows selected operations in a substrate processing method 100 for forming a patterned MIM structure according to embodiments of the present technology. It should be appreciated that method 100 may also include one or more operations prior to the initiation of the method, including front-end processing, deposition, etching, polishing, cleaning, and any operations that may be performed before the described operations. Embodiments of method 100 may further include one or more optional operations that may or may not be specifically associated with the operations described. For example, many of the described operations may be performed with alternative operations and techniques that are also covered under the scope of the present technology.

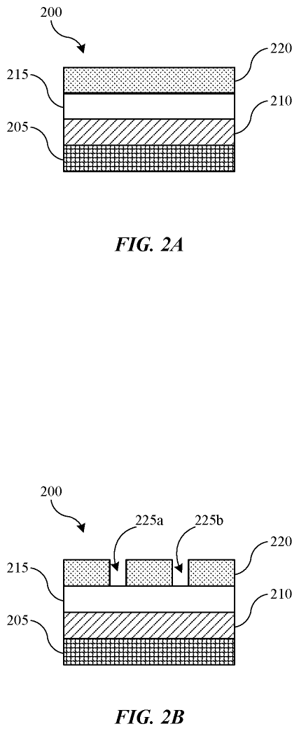

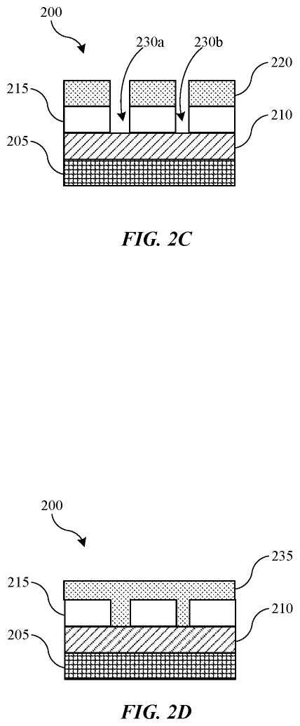

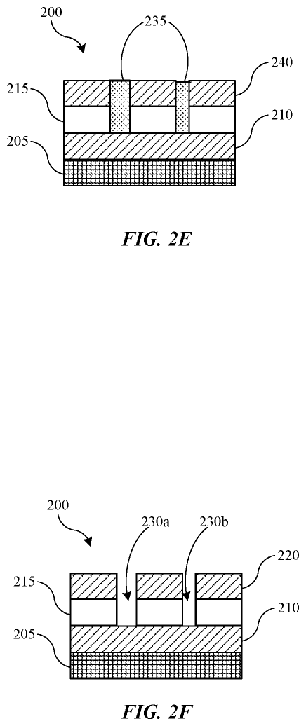

FIGS. 2A-F show partial cross-sectional views of substrate structure 200 at various points in the operations of method 100. It should be understood that FIGS. 2A-F only illustrate partial cross-sections, and the substrate structure may include any number of additional materials and features, having a variety of characteristics and aspects, that are not shown in the figures. It should also be understood that not all operations in method 100 may be fully represented in substrate structure 200, and not all the features shown in substrate structure 200 may be formed by an operation that is explicitly described by method 100.

Method 100 may include providing a substrate at operation 105. The provided substrate may be substrate 200 shown in FIG. 2A that includes a silicon-containing substrate layer 205, a first metal layer 210 in contact with the substrate layer 205, and a scandium-doped aluminum nitride layer 215 in contact with the first metal layer 210. The substrate 200 may also include a temporary, first photoresist layer 220 formed on the scandium-doped aluminum nitride layer 215.

In embodiments, the silicon-containing substrate layer 205 may be made of one or more kinds of silicon, including polysilicon and single-crystal silicon. In further embodiments, the silicon-containing substrate layer 205 may include silicon oxide. In still further embodiments, the silicon oxide may be formed or deposited on a silicon material such as polysilicon or single-crystal silicon, among other types of silicon. In yet additional embodiments, the silicon-containing substrate layer 205 may be the base layer of a silicon wafer.

In additional embodiments, the substrate 200 may optionally include an undoped aluminum nitride layer (AlN) positioned on the silicon-containing substrate layer 205. In embodiments, the undoped AlN layer may act as an adhesion layer between the silicon-containing substrate layer 205 and the first metal layer 210. In additional embodiments, the undoped AlN layer may also act as a seed layer for the formation of the first metal layer 210. In further embodiments, the undoped AlN layer may be formed with a non-zero thickness of less than or about 200 nm, less than or about 175 nm, less than or about 150 nm, less than or about 125 nm, less than or about 110 nm, less than or about 100 nm, less than or about 90 nm, less than or about 80 nm, less than or about 70 nm, less than or about 60 nm, less than or about 50 nm, or less.

In further embodiments, the first metal layer 210 may be made of one or more metals such as molybdenum, aluminum, and titanium, among other metals. The first metal layer 210 may act as an electrode in a piezoelectric MIM structure. In still further embodiments, the first metal layer 210 may be made from unalloyed molybdenum. In yet further embodiments, the first metal layer 210 may have a non-zero thickness of less than or about 200 nm, less than or about 190 nm, less than or about 180 nm, less than or about 170 nm, less than or about 160 nm, less than or about 150 nm, or less.

In additional embodiments, the scandium-doped aluminum nitride layer 215 may form the patterned piezoelectric material in a MIM structure of substrate 200. In embodiments, the layer 215 may include scandium doping at levels of greater than or about 5 mol. %, greater than or about 10 mol. %, greater than or about 15 mol. %, greater than or about 20 mol. %, greater than or about 25 mol. %, greater than or about 30 mol. %, greater than or about 32.5 mol. %, greater than or about 35 mol. %, greater than or about 37.5 mol. %, greater than or about 40 mol. %, greater than or about 42.5 mol. %, greater than or about 45 mol. %, or more. In additional embodiments, the scandium may be uniformly distributed in the scandium-doped aluminum nitride layer 215. In still more embodiments, the scandium may have a gradient distribution in the scandium-doped aluminum nitride layer 215 where the surface of the layer 215 in contact with the metal layer 210 has a lower or higher scandium level than the surface of the layer 215 facing opposite the contact surface. In further embodiments, the scandium-doped aluminum nitride layer 215 may have a thickness of greater than or about 500 nm, greater than or about 600 nm, greater than or about 700 nm, greater than or about 800 nm, greater than or about 900 nm, greater than or about 1000 nm, or more.

In more embodiments, the temporary, photoresist layer 220 is formed on the scandium-doped aluminum nitride layer 215 to prepare for the patterned etch of the ScAlN layer. The photoresist layer 220 may be made of a photosensitive organic polymer that can resist significant removal by the wet etching composition that makes contact with the portions of the scandium-doped aluminum nitride layer 215 that are exposed by the patterned photoresist layer. In additional embodiments, the photoresist layer may include an epoxy-containing photoresist material.

Method 100 further includes patterning the photoresist layer 220 at operation 110. In embodiments, the patterning operation creates exposed portions on a surface of the scandium-doped aluminum nitride layer 215 that will start etching when the substrate 200 comes into contact with the wet etching solution. FIG. 2B shows patterned openings 225a-b formed into the photoresist layer 220 following photolithographic patterning operation.

Method 100 still further includes etching the scandium-doped aluminum nitride layer 215 at operation 115. FIG. 2C shows some of the patterned openings 230a-b formed in the scandium-doped aluminum nitride layer 215 at the completion of an etching operation 115. The etching operation may include contacting the substrate 200, which includes the patterned photoresist layer 220, with a wet etching composition. In embodiments, the wet etching composition may include phosphoric acid (H₃PO₄). In further embodiments, the concentration of the phosphoric acid may be greater than or about 80 wt. %, greater than or about 81 wt. %, greater than or about 82 wt. %, greater than or about 83 wt. %, greater than or about 84 wt. %, greater than or about 85 wt. %, or more. The etching composition may be free of any compounds that reduce the etching selectivity of the composition for the scandium-doped aluminum nitride layer 215 relative to the metal layer 210. In embodiments, the etching composition may be free of other inorganic acids, such as nitric acid (HNO₃), sulfuric acid (H₂SO₄), and hydrochloric acid (HCl), among other inorganic acids. In further embodiments, the etching composition may be free of organic acids such as formic acid and acetic acid, among other organic acids. In yet additional embodiments, the etching composition may be free of alkaline compounds such as potassium hydroxide (KOH), sodium hydroxide (NaOH), and tetramethylammonium hydroxide (TMAH), among other alkaline compounds. In still more embodiments, the etching composition may consist of phosphoric acid and water.

In embodiments, the patterned substrate 200 and the etching composition may be contacted at an etching composition temperature of greater than or about 90° C. In additional embodiments, the etching composition may be characterized by a contact temperature of greater than or about 95° C., greater than or about 100° C., greater than or about 105° C., greater than or about 110° C., greater than or about 115° C., greater than or about 120° C., greater than or about 125° C., greater than or about 130° C., or more. The elevated temperature of the etching composition elevates the etching rate of the scandium-doped aluminum nitride layer 215. In embodiments, the etching operation 115 may be characterized by a ScAlN etching rate of greater than or about 110 nm/min, greater than or about 120 nm/min, greater than or about 130 nm/min, greater than or about 140 nm/min, greater than or about 150 nm/min, greater than or about 160 nm/min, greater than or about 170 nm/min, greater than or about 180 nm/min, greater than or about 190 nm/min, greater than or about 200 nm/min, or more.

In still further embodiments, a one micron thick layer 215 of the scandium-doped aluminum nitride may be etched through from a top surface in contact with the photoresist layer 220 to a bottom surface in contact with the metal layer 210 in less than or about 5 minutes, less than or about 4 minutes, less than or about 3 minutes, less than or about 2 minutes, or less. In contrast, a lower temperature etching composition of 85° C. or less, which is characterized by a ScAlN etch rate of less than or about 100 nm/min, would etch through the one micron thick layer 215 in greater than or about 10 minutes. Embodiments of the present technology enable etching operation times that are significantly shorter than etching operations that use lower-selectivity, lower-temperature etching compositions. In embodiments, the etching operations may be less than or about half the time or less.

As noted above, the high selectivity of the etching composition for the scandium-doped aluminum nitride over the underlying metal in the metal layer 210 permits increased etch rates without overetching the metal layer. In embodiments the selectivity of the etching composition for etching the scandium-doped aluminum nitride layer 215 relative to the metal layer 210 may be greater than or about 1000:1, greater than or about 5000:1, greater than or about 10,000:1, greater than or about 25,000:1, greater than or about 50,000:1, greater than or about 75,000:1, greater than or about 100,000:1, or more. In further embodiments, the high selectivity of the etching composition is characterized by an etch rate for the metal layer 210 of less than or about 10 nm/hour, less than or about 5 nm/hour, less than or about 1 nm/hour, less than or about 0.5 nm/hour, less than or about 0.1 nm/hour or less. In embodiments, the low etch rate of the metal layer 210 by the etching composition prevents an overetched recess on the exposed regions of the scandium-doped aluminum nitride layer 215.

Method 100 may also include the formation of a temporary, resist layer 235 on the patterned scandium-doped aluminum nitride layer 215 at operation 120. As shown in FIG. 2D, the resist layer 235 may fill the openings 230a-b in the patterned scandium-doped aluminum nitride layer 215 and cover the top surface of the patterned layer 215. In further embodiments, the resist layer 235 may be made from an organic polymer material or other material that prevents the formation of the second metal layer in areas that are not patterned on the resist layer 235. In yet more embodiments, the resist layer 235 may be a photoresist layer that can be photolithographically patterned at operation 125 for the subsequent formation of a patterned second metal layer on the patterned scandium-doped aluminum nitride layer 215.

Method 100 may further include the formation of a patterned second metal layer 240 at operation 130. FIG. 2E shows a portion of the second metal layer 240 formed on the patterned scandium-doped aluminum nitride layer 215. The unremoved portions of the resist layer 235 that remain after operation 125 prevent the deposition of the metal in the second metal layer 240 from filling the openings in the patterned scandium-doped aluminum nitride layer 215. In an additional operation, the unremoved portions of the resist layer 235 are removed to form a MIM structure in substrate 200, as shown in FIG. 2F. In embodiments, the second metal layer 240 may be made of one or more metals such as molybdenum, aluminum, titanium, platinum, and ruthenium, among other metals. In further embodiments, the second metal layer 240 may be made of the same metal as the first metal layer 210. In further embodiments, the second metal layer 240 may have an average surface roughness of less than or about 10 nm, less than or about 9 nm, less than or about 8 nm, less than or about 7 nm, less than or about 6 nm, less than or about 5 nm, less than or about 4 nm, less than or about 3 nm, less than or about 2 nm, less than or about 1 nm, or less.

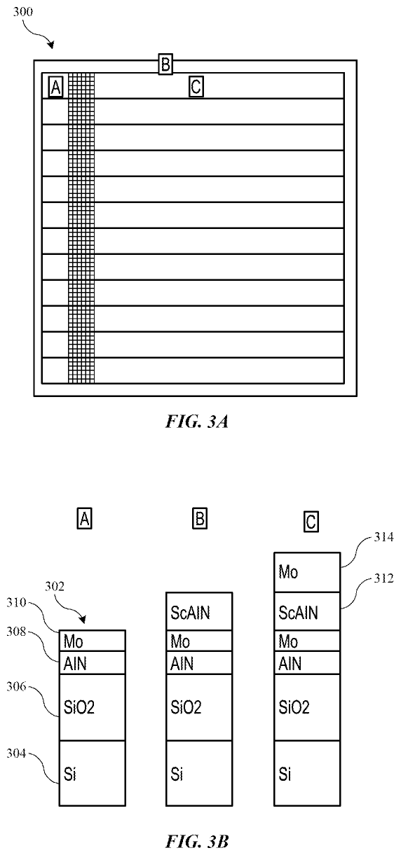

Embodiments of the present methods can form a MIM device like the device 300 shown in FIG. 3A. In embodiments, device 300 may include a base substrate 302 that includes a silicon layer 304, a silicon oxide layer 306, an aluminum nitride adhesion layer 308, and a first, molybdenum metal layer 310. In further embodiments, a patterned scandium-doped aluminum nitride layer 312 and second, molybdenum metal layer 314 are deposited and etched according to embodiments of the present methods. FIG. 3A identifies a first region “A” in device 300 that includes the base substrate 302 without the overlying scandium-doped aluminum nitride layer 312 or second, molybdenum metal layer 314. The figure also identifies a second region “B” that includes the base substrate 302 and portions of the patterned scandium-doped aluminum nitride layer 312, but not the second, molybdenum metal layer 314. The figure further identifies a third region “C” that includes all three of the base substrate 302, portions of the patterned scandium-doped aluminum nitride layer 312, and portions of the second, molybdenum metal layer 314. Cross-sections of regions “A”, “B”, and “C” are shown in FIG. 3B.

Embodiments of the present technology provide highly selective etching operations for scandium-doped aluminum nitride layers. The highly selective etching reduces overetching of the ScAlN material into adjacent metal layers. In addition, the highly selective etching permits the operation to be conducted at increased etch rates without concern about extensive overetching in the metal layer. In embodiments, the etching operations can form a patterned scandium-doped aluminum nitride layer with a precisely formed etch stop at the exposed surface of the underlying metal layer. The etching operation can be performed in significantly less time than a conventional etching operation concerned about overetching. In many cases, etching operations according to the present technology are performed in less than half the time of a conventional etching operation.

In the preceding description, for the purposes of explanation, numerous details have been set forth in order to provide an understanding of various embodiments of the present technology. It will be apparent to one skilled in the art, however, that certain embodiments may be practiced without some of these details, or with additional details. For example, other substrates that may benefit from the wetting techniques described may also be used with the present technology.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. Where multiple values are provided in a list, any range encompassing or based on any of those values is similarly specifically disclosed.

As used herein and in the appended claims, the singular forms “a”, “an”, and “the” include plural references unless the context clearly dictates otherwise. Thus, for example, reference to “a material” includes a plurality of such materials, and reference to “the period of time” includes reference to one or more periods of time and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A substrate processing method comprising:
providing a scandium-doped aluminum nitride layer on a metal layer;
etching a portion of the scandium-doped aluminum nitride layer with an etching composition, wherein the etching composition comprises greater than or about 80 wt. % phosphoric acid, and wherein the etching composition is characterized by a temperature of greater than or about 90° C. during etching.

2. The substrate processing method of claim 1, wherein the etching composition is free of nitric acid.

3. The substrate processing method of claim 1, wherein the etching composition is free of potassium hydroxide and tetramethyl ammonium hydroxide.

4. The substrate processing method of claim 1, wherein the etching composition etches the scandium-doped aluminum nitride layer at an etch rate of greater than or about 110 nm/min.

5. The substrate processing method of claim 1, wherein the etching composition etches the metal layer at an etch rate of less than or about 1 nm/hour.

6. The substrate processing method of claim 1, wherein a patterned photoresist having one or more openings is formed on the scandium-doped aluminum nitride layer, and wherein the etching composition etches the portion of the scandium-doped aluminum nitride layer through the one or more openings in the patterned photoresist.

7. The substrate processing method of claim 1, wherein the scandium-doped aluminum nitride layer comprises greater than or about 30 mol. % scandium.

8. The substrate processing method of claim 1, wherein the metal layer comprises molybdenum.

9. A substrate processing method comprising:
providing the substrate, which includes a scandium-doped aluminum nitride layer on a metal layer;
forming a patterned photoresist layer on the scandium-doped aluminum nitride layer, wherein the patterned photoresist layer comprises one or more openings that expose a portion of the scandium-doped aluminum nitride layer;
contacting the substrate with an etching solution, wherein the etching solution is characterized by a temperature greater than or about 90° C. and a phosphoric acid concentration of greater than or about 80 wt. %; and
etching the exposed portion of the scandium-doped aluminum nitride layer with the etching solution.

10. The substrate processing method of claim 9, wherein the etching solution is free of nitric acid, potassium hydroxide, and tetramethyl ammonium hydroxide.

11. The substrate processing method of claim 9, wherein the etching solution is characterized by an etch rate selectivity ratio for the scandium-doped aluminum layer over the metal layer of greater than or about 10,000:1.

12. The substrate processing method of claim 9, wherein the etching solution etches the scandium-doped aluminum nitride layer at a first etch rate of greater than or about 110 nm/min, and etches the metal layer at a second etch rate of less than or about 1 nm/hour.

13. The substrate processing method of claim 9, wherein the scandium-doped aluminum nitride layer comprises greater than or about 30 mol. % scandium.

14. The substrate processing method of claim 9, wherein the metal layer comprises molybdenum.

15. A structured substrate comprising:
a silicon-containing material;
a first metal layer in contact with the silicon-containing material;
a patterned scandium-doped aluminum nitride layer in contact with the first metal layer, wherein the patterned scandium-doped aluminum nitride layer has greater than or about 30 mol. % scandium; and
a patterned second metal layer in contact with a surface of the patterned scandium-doped aluminum nitride layer opposite a surface in contact with the first metal layer.

16. The structured substrate of claim 15, wherein the silicon-containing material comprises a silicon oxide layer in contact with the first metal layer and a silicon layer in contact with the silicon oxide layer.

17. The structured substrate of claim 15, wherein the structured substrate further comprises an undoped aluminum nitride layer in contact with the silicon-containing material and the first metal layer.

18. The structured substrate of claim 15, wherein the first metal layer comprises unalloyed molybdenum.

19. The structured substrate of claim 15, wherein the second metal layer comprises molybdenum.

20. The structured substrate of claim 15, wherein the first metal layer lacks an overetched recess above a gap in the patterned scandium-doped aluminum nitride layer.
